(19) United States
(12) Patent Application Publication
(10) Pub. No.: US 2009/0034109 A1
(43) Pub. Date: Feb. 5, 2009

(54) DISK DRIVE APPARATUS AND MEDIA DEFECT DETECTION METHOD

(75) Inventors: Stephen G. Paul, Santa Cruz, CA (US); Dar-Der Chang, San Jose, CA (US)

Correspondence Address: SCHWEGMAN, LUNDBERG & WOESSNER/TOSHIBA, P.O. BOX 2938, MINNEAPOLIS, MN, 55402, US

(73) Assignee: Kabushiki Kaisha Toshiba 1-1, Tokyo (JP)

(21) Appl. No.: 11/830,724

(22) Filed: Jul. 30, 2007

(51) Int. Cl. G11B 5/09; G11B 27/36; G11C 29/00

(52) U.S. Cl. 360/53; 360/31; 360/75; 714/718

(57) ABSTRACT

According to one embodiment, a disk drive apparatus includes a defect table formed using more than one defect detection standard. Methods and devices are described using different defect detection standards to detect and map defects of different sizes and in specific regions that can affect drive operation. Also, methods and devices are described that provide fast and efficient defect scanning in selected regions due to utilization of error correction systems. Methods are shown where during defect detection a read/write gate assertion is triggered using a servo gate pulse.

### BACKGROUND

A disk drive is an information storage device. A disk drive includes one or more disks clamped to a rotating spindle and at least one head for reading information representing data from and/or writing data to the surfaces of each disk. The head is supported by a suspension coupled to an actuator that may be driven by a voice coil motor. Control electronics in the disk drive provide electrical pulses to the voice coil motor to move the head to desired positions on the disks to read and write the data in tracks on the disks and to park the head in a safe area when not in use or when otherwise desired for protection of the disk drive.

Although it is desirable to have zero defects on the surface of a disc, inevitably some level of defects exists. A common solution to managing disc drive operation with media defects is to scan the disc surface for defects, and create a map or defect table containing the defect locations. In this way, the defects can be avoided when reading or writing data to the disc. However, there is always a need to improve defect detection ability to ensure reliable drive operation.

### BRIEF DESCRIPTION OF THE DRAWINGS

FIG. 1 is a perspective view of a magnetic recording and reproducing apparatus (hard disk drive) according to an example embodiment;

FIG. 2 is a schematic plan view of a magnetic disk according to an example embodiment;

FIG. 3 is a perspective view of a data zone in a magnetic disk according to an example embodiment;

FIG. 4 is a schematic diagram showing a servo zone and a data zone in a magnetic disk according to an example embodiment;

FIG. 5 is a plan view showing patterns in a servo zone and a data zone in a magnetic disk according to an example embodiment;

FIG. 6 is a block diagram of the magnetic recording and reproducing apparatus (hard disk drive) according to an example embodiment;

FIG. 7 is a schematic diagram of sector pulses and magnetic media regions.

FIG. 8 is a schematic timing diagram of selected disk drive functions.

FIG. 9 is a block diagram of a magnetic recording and reproducing apparatus (hard disk drive) according to an example embodiment;

FIG. 10 is an example block diagram of a computer system for implementing methods and devices as described in accordance with example embodiments.

### DETAILED DESCRIPTION

Hereinafter, example embodiments of the present invention will be described with reference to the drawings.

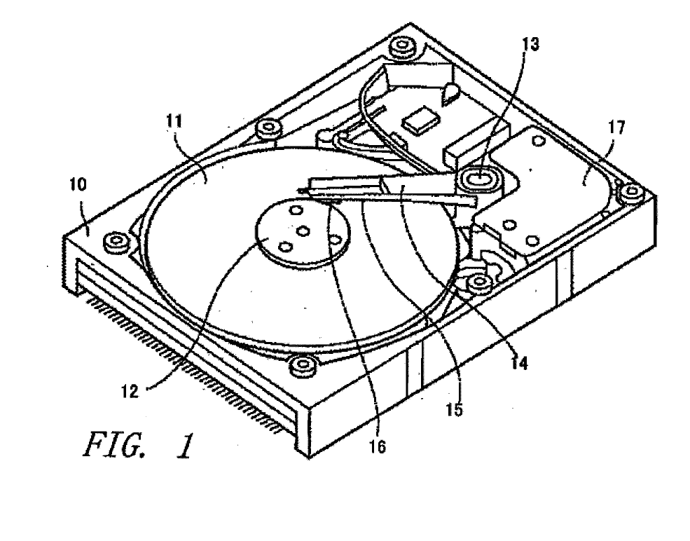

FIG. 1 is a perspective view of a magnetic recording and reproducing apparatus (hard disk drive) according to an embodiment. The magnetic recording and reproducing apparatus comprises, inside a chassis 10, a magnetic disk 11, a head slider 16 including a read head and a write head, a head suspension assembly (a suspension 15 and an actuator arm 14) that supports the head slider 16, a voice coil motor (VCM) 17 and a circuit board.

The magnetic disk (discrete track media) 11 is mounted on and rotated by a spindle motor 12. Various digital data are recorded on the magnetic disk 11 in a perpendicular magnetic recording manner. In an example embodiment, the magnetic head incorporated in the head slider 16 is an integrated head including a write head of a single pole structure and a read head using a shielded magneto resistive (MR) read element (such as a GMR film or a TMR film). The suspension 15 is held at one end of the actuator arm 14 to support the head slider 16 to face the recording surface of the magnetic disk 11. The actuator arm 14 is attached to a pivot 13. The voice coil motor (VCM) 17, which drives the actuator, is provided at the other end of the actuator 14. The VCM 17 drives the head suspension assembly to position the magnetic head at an arbitrary radial position of the magnetic disk 11. The circuit board comprises a head IC to generate driving signals for the VCM and control signals for controlling read and write operations performed by the magnetic head.

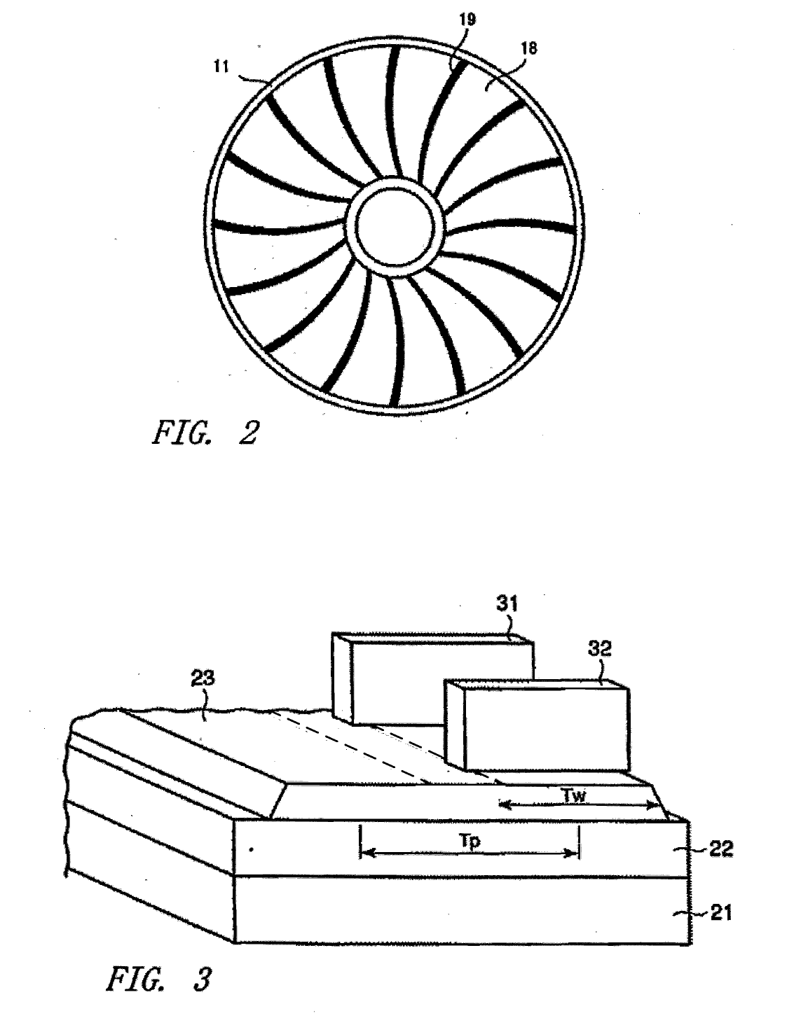

FIG. 2 is a schematic plan view of a magnetic disk 11 according to an embodiment. FIG. 2 shows data zones 18 and servo zones 19. User data is recorded in each of the data zones 18. This example magnetic disk has tracks formed of concentric magnetic patterns. The recording tracks will be described later by way of example with reference to FIG. 3. Servo data for head positioning is formed in each of the servo zones 19 as patterns of a differently magnetized material. On the disk surface, the servo zone 19 is shaped like a circular arc corresponding to a locus of a head slider during access.

FIG. 3 is a perspective view of one example of a data zone in a magnetic disk media according to an embodiment. A soft underlayer 22 is formed on a substrate 21. Magnetic patterns constituting the recording tracks 23. The radial width and track pitch of the recording track 23 are denoted as Tw and Tp, respectively. A GMR element 31 of a read head and a single pole 32 of a write head, which are formed in the head slider, are positioned above the recording track 23.

As the substrate 21, a flat glass substrate may be used. The substrate 21 is not limited to the glass substrate but an aluminum substrate (or any other suitable substrate) may be used. A magnetic material is placed onto the substrate 21 and selectively magnetized to form recording tracks. A magnetic material such as recording track 23, CoCrPt may be used, although the invention is not so limited. Although not shown, a protective film of diamond-like carbon (DLC) may be formed on the surfaces of the media. In one example, lubricant may be applied to the surface of the protective film.

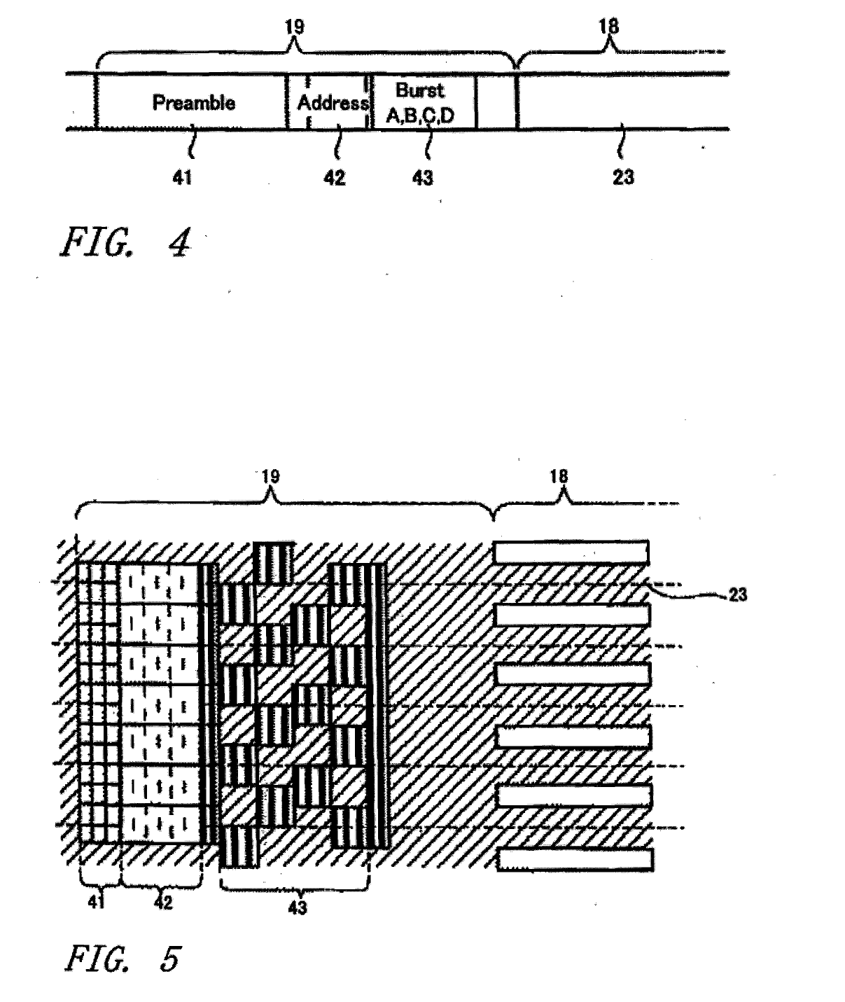

With reference to FIGS. 4 and 5, the patterns of the servo zone and data zone will be described. As schematically shown in FIG. 4, the servo zone 19 includes a preamble section 41, an address section 42, and a burst section 43 for detecting deviation.

As shown in FIG. 5, the data zone 18 includes the recording tracks 23. Patterns of the magnitization which provide servo signals are formed in each of the preamble section 41, address section 42, and burst section 43 in the servo zone 19. These sections may have the functions described below.

The preamble section 41 is provided to execute a phase lock loop (PLL) process for synthesizing a clock for a servo signal read relative to deviation caused by rotational deflection of the media, and an AGC process for maintaining appropriate signal amplitude.

The address section 42 may have servo signal recognition codes called servo marks, sector data, cylinder data, and the like formed at the same pitch as that of the preamble section 41 in the circumferential direction using encoding, for example Manchester, or other types of encoding. In particular, since the cylinder data has a pattern exhibiting a data varied for every servo track to provide the minimum difference between adjacent tracks so as to reduce the adverse effect of address reading errors during a seek operation.

The burst section 43 is an off-track detecting region used to detect the amount of off-track with respect to the on-track state for a cylinder address. The burst section 43 includes patterns to locate a read or write head with respect to a desired track center. A pattern in FIG. 5 is shown by way of example including four fields of burst marks (A, B, C, and D), whose pattern phases in a radial direction are shifted to each other in respective fields. Other burst patterns could also be used. In one example, plural marks are arranged at the same pitch as that of the preamble section in the circumferential direction.

The principle of detection of a position on the basis of the burst section 43 will not be described in detail. When using the pattern shown, the off-track amount is obtained by calculating the average amplitude value of read signals from the A, B, C, and D bursts. As discussed above, other patterns may be used that do not depend on average amplitude.

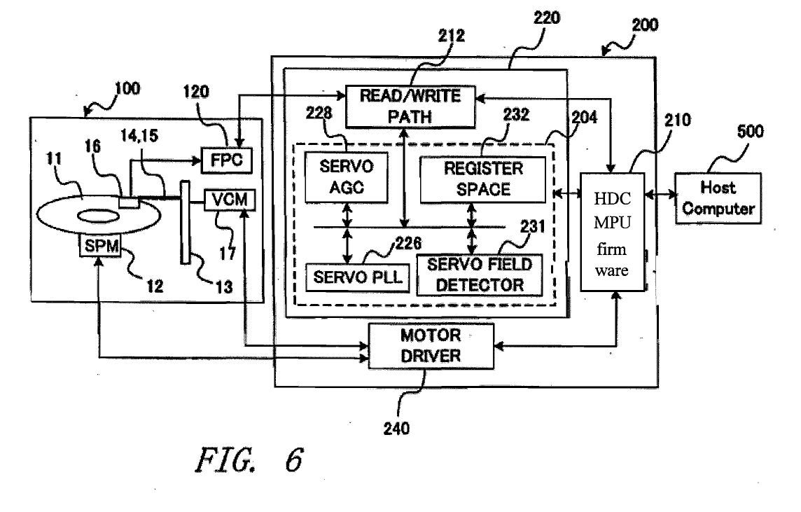

FIG. 6 shows a block diagram of the magnetic recording and reproducing apparatus (hard disk drive) according to an example embodiment. This figure shows the head slider 16 only above the top surface of the magnetic disk 11. However, the magnetic recording layer is formed on each side of the magnetic disk. A down head and an up head are provided above the bottom and top surfaces of the magnetic disk, respectively. The disk drive includes a main body unit called a head disk assembly (HDA) 100 and a printed circuit board (PCB) 200.

As shown in FIG. 6, the HDA 100 has the magnetic disk 11, the spindle motor 12, which rotates the magnetic disk 11, the head slider 16, including the read head and the write head, the suspension 15 and actuator arm 14, the VCM 17, and a head amplifier (HIC), which is not shown. The head slider 16 is provided with the read head including a read element 31, such as a giant magnetoresistive (GMR) element and the write head 32, which are shown in FIG. 3.

The head slider 16 may be elastically supported by a gimbal provided on the suspension 15. The suspension 15 is attached to the actuator arm 14, which is rotatably attached to the pivot 13. The VCM 17 generates a torque around the pivot 13 for the actuator arm 14 to move the head in the radial direction of the magnetic disk 11. The HIC is fixed to the actuator arm 14 to amplify input signals to and output signals from the head. The HIC is connected to the PCB 200 via a flexible cable 120. Providing the HIC on the actuator arm 14 may effectively reduce noise in the head signals. However, the HIC may be fixed to the HDA main body.

As described above, the magnetic recording layer is formed on each side of the magnetic disk 11, and the servo zones 19, each shaped like a circular arc, are formed so as to correspond to the locus of the moving head. The specifications of the magnetic disk meet outer and inner diameters and read/write characteristics adapted to a particular drive. The radius of the circular arc formed by the servo zone 19 is given as the distance from the pivot to the magnet head element.

In the illustrated example embodiment, several major electronic components, so-called system LSIs, are mounted on the PCB 200. The system LSIs are a controller 210, a read/write channel IC 220, and a motor driver IC 240. The controller 210 includes a disk controller (HDC) and an MPU, and firmware. In one embodiment, the firmware is configured for defect detection methods as described below. In one embodiment, defect detection is controlled by a system external to the hard disk drive during a stage of the manufacturing and testing of the hard disk drive.

The MPU is a control unit of a driving system and includes ROM, RAM, CPU, and a logic processing unit that implements a head positioning control system according to the present example embodiment. The logic processing unit is an arithmetic processing unit comprised of a hardware circuit to execute high-speed calculations. Firmware for the logic processing circuit is saved to the ROM or elsewhere in the disk drive. The MPU controls the drive in accordance with firmware.

The disk controller (HDC) is an interface unit in the hard disk drive which manages the whole drive by exchanging information with interfaces between the disk drive and a host computer 500 (for example, a personal computer) and with the MPU, read/write channel IC 220, and motor driver IC 240.

The read/write channel IC 220 is a head signal processing unit relating to read/write operations. The read/write channel IC 220 is shown as including a read/write path 212 and a servo demodulator 204. The read/write path 212, which can be used to read and write user data and servo data, may include front end circuitry useful for servo demodulation. The read/write path 212 may also be used for writing servo information in self-servowriting. It should be noted that the disk drive also includes other components, which are not shown because they are not necessary to explain the example embodiments.

The servo demodulator 204 is shown as including a servo phase locked loop (PLL) 226, a servo automatic gain control (AGC) 228, a servo field detector 231 and register space 232. The servo PLL 226, in general, is a control loop that is used to provide frequency and phase control for the one or more timing or clock circuits (not shown in FIG. 6) within the servo demodulator 204. For example, the servo PLL 226 can provide timing signals to the read/write path 212. The servo AGC 228, which includes (or drives) a variable gain amplifier, is used to keep the output of the read/write path 212 at a substantially constant level when servo zones 19 on one of the disks 11 are being read. The servo field detector 231 is used to detect and/or demodulate the various subfields of the servo zones 19, including a SAM, a track number, a first phase servo burst, and a second phase servo burst. The MPU is used to perform various servo demodulation functions (e.g., decisions, comparisons, characterization and the like) and can be thought of as being part of the servo demodulator 204. In the alternative, the servo demodulator 204 can have its own microprocessor.

One or more registers (e.g., in register space 232) can be used to store appropriate servo AGC values (e.g., gain values, filter coefficients, filter accumulation paths, etc.) for when the read/write path 212 is reading servo data, and one or more registers can be used to store appropriate values (e.g., gain values, filter coefficients, filter accumulation paths, etc.) for when the read/write path 212 is reading user data. A control signal can be used to select the appropriate registers according to the current mode of the read/write path 212. The servo AGC value(s) that are stored can be dynamically updated. For example, the stored servo AGC value(s) for use when the read/write path 212 is reading servo data can be updated each time an additional servo zone 19 is read. In this manner, the servo AGC value(s) determined for a most recently read servo zone 19 can be the starting servo AGC value(s) when the next servo zone 19 is read.

The read/write path 212 includes the electronic circuits used in the process of writing and reading information to and from the magnetic disks 11. The MPU can perform servo control algorithms, and thus, may be referred to as a servo controller. Alternatively, a separate microprocessor or digital signal processor (not shown) can perform servo control functions.

As discussed above, the magnetic disk 11 includes regions of magnetic media upon which information is stored. Although a perfect magnetic media surface would be desirable, a number of regions that include defects are inevitable. In embodiments shown, a hard disk drive operates despite the media defects by first detecting defects present on the surface of the magnetic disk 11 and mapping the locations of the defects to a defect table or the like. During data read/write operations, the defect table is checked, and the regions where defects are located are avoided, thus leaving the remaining regions of the magnetic disk 11 fully functional. In one method of defect detection such as a tone scan method, data is written to the magnetic disk and then later read. Differences between the data written and the data read are checked and locations of the differences are mapped.

Defects that are larger than a threshold size are not usable, and therefore the size and location of these defects are mapped to the defect table to be avoided. Some defects are below the threshold size, and while they are detectable as defects, they are not sufficiently large to require avoidance during drive operation. In one embodiment, with such small defects, an error correction system or code (ECC) is employed to enable use of the media region containing the small defect.

However, some regions of the magnetic disk 11 are more sensitive to small defects, and ECC is unable to correct for defects in these regions. For example, a sector pulse region includes information to sync the read/write head to the timing used for data access in a following data region on the magnetic disk. In one example, it is possible for a small defect adjacent to a sync mark to affect drive operation.

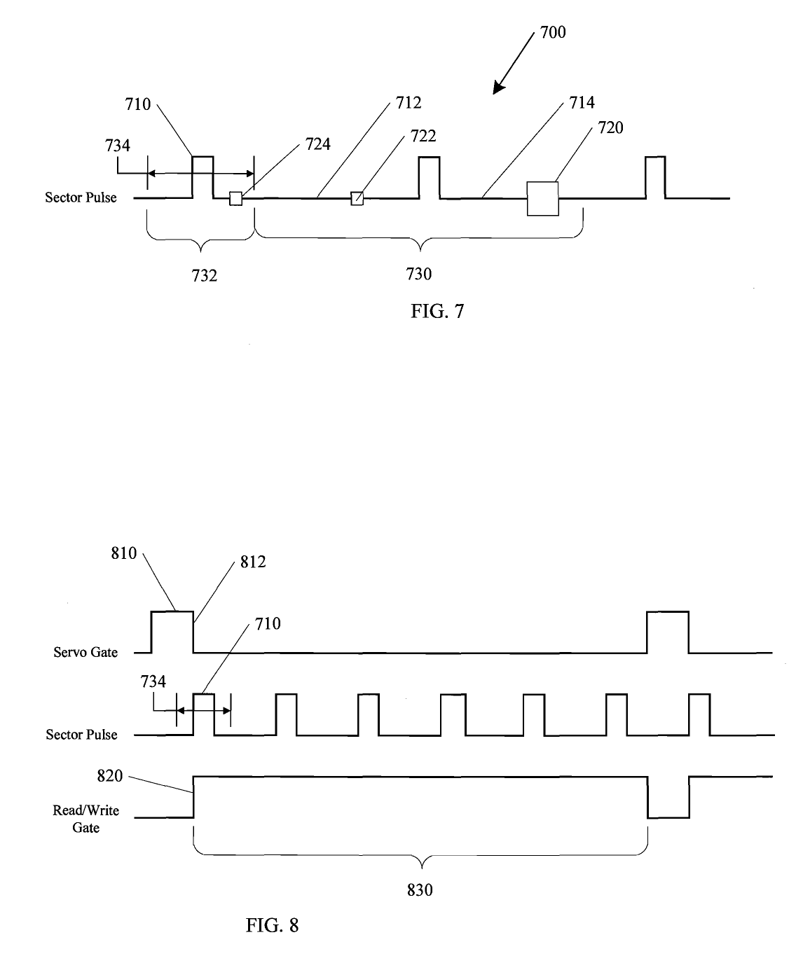

One mechanism where a small defect adjacent to a sync mark affects drive operation includes drive motor jitter. The motor that drives the magnetic disk 11 includes a bearing with a small, but measurable, bearing jitter tolerance. At different times during drive operation, the data written on the magnetic disk can be located at slightly different locations within the jitter tolerance. An effect of motor jitter is further illustrated in FIG. 7 and discussed along with embodiments of the present invention below.

FIG. 7 shows a schematic diagram of a magnetic media track 700 and associated sector pulses 710 within the track 700. A first sector 712 and a second sector 714 are shown between sector pulses 710. A data region 730 is shown along with a sector pulse region 732. The sector pulse region 732 includes important information for hardware operation such as a sync mark to facilitate reading of data in the following data region 730.

The sector pulse region 732 is shown with a window size 734 that encompasses the sector pulse 710. A large defect 720 is shown within the second sector 714 and a small defect 722 is shown within the data region 730 of the first sector 712. As discussed above, in one embodiment, the large defect 720 is larger than a threshold size, and the defect information is cataloged in the defect table. In one embodiment, the threshold defect size is determined by an ECC system present in the drive. In other words, a defect smaller than the threshold size can be compensated for during drive operation using ECC, therefore the defect is not mapped.

In FIG. 7, the large defect 720 is not correctable using ECC therefore, the large defect 720 is mapped. In one example the second sector 714 containing the large defect 720 is listed in a defect table as unusable. The small defect 722 (still within the data region 730) is smaller than the threshold size therefore, the small defect 722 is not mapped. During operation, the small defect 722 is compensated for using ECC.

As discussed above, selected regions are more sensitive to small defects. For example, small defect 724 is illustrated in FIG. 7 as the same size as small defect 722 however, small defect 724 is located within the sector pulse region 732, adjacent to the sector pulse 710. In one embodiment, ECC is not effective within the sector pulse region 732, and the small defect 724 can affect drive operation.

If a sensitive piece of data, for example a sync mark is written close to the small defect 724, it is possible for the drive to operate normally if the small defect 724 is avoided. However, if a mechanism such as motor jitter moves the data written on the magnetic disk 11 slightly, then the sync mark can fall within the small defect 724 causing drive errors in reading the adjacent data region 730.

In one embodiment, small defects such as defect 724 are detected and mapped due to their potential contribution to drive error. In one example the first sector 712 associated with the defect 724 is mapped and avoided. In one embodiment, a first defect detection standard is applied to a first region such as the data region 730. In the first region, a threshold for defect detection includes an ECC threshold above which ECC cannot correct. If ECC can correct the read error, generally there is no defect. In one embodiment, once a defect is found, the entire sector is mapped out as a unit to the defect table and the entire sector is avoided in the future.

In one embodiment, a second defect detection standard is applied to a second region such as the sector pulse region 732. Under the second defect detection standard, the small defect 724 is detected and mapped. In one embodiment, the sector pulse region 732 is centered around the sector pulse 710, although the invention is not so limited. In one example the sector pulse region 732 is centered around a sync mark adjacent to the sector pulse 710. Centering the sector pulse region 732 around the sector pulse 710 is useful because it accounts for an amount of drive motor tolerance, as will be discussed in more detail below. In one embodiment, the window size 734 is equal to or larger than a drive motor jitter tolerance.

Using methods as described above, defects of different sizes that can affect drive operation are all detected and mapped. More magnetic disk area is utilized by employing ECC in regions where it is effective.

Although a data region and a sector pulse region are discussed as examples, the invention is not so limited. Other types of regions on a magnetic disk benefiting from different standards of defect detection are also within the scope of the present disclosure.

FIG. 8 illustrates a timing diagram of selected disk drive functions. A servo gate pulse 810 is shown as it corresponds to sector pulses 710 and a read/write gate assertion 820. In one embodiment, the read/write gate assertion 820 is triggered using the servo gate pulse 810, in contrast to using the sector pulse 710. Using the servo gate pulse 810 allows the read/write head to check for defects in regions that are adjacent to the sector pulse as described in embodiments above.

In one embodiment, a falling edge 812 of the servo gate pulse 810 is used to trigger assertion of the read/write gate. As shown in FIG. 8, the read/write gate assertion 820 lines up with the falling edge 812 of the servo gate pulse 810. In other embodiments, the read/write gate assertion 820 is coordinated with another aspect of the servo gate. In one embodiment, the read/write gate is asserted at a selected time after the falling edge 812 of the servo gate pulse 810.

In one embodiment, the read/write gate assertion 820 is triggered using the servo gate pulse 810, and further as described above, more than one standard of defect detection is employed over the magnetic disk 11 to detect defects of varying sizes in different regions. In one embodiment methods of triggering of the read/write gate assertion 820 using the servo gate pulse 810 are only used during defect detection. Selected methods use sector pulses to trigger read/write gates during normal drive operation.

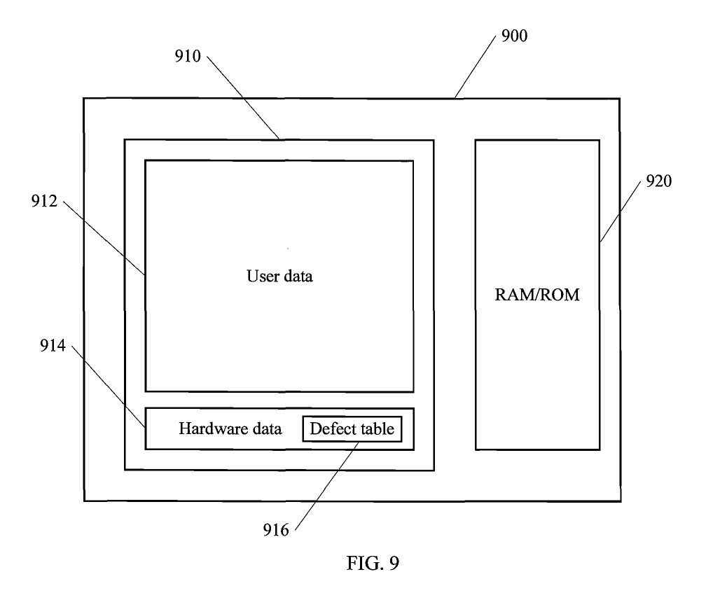

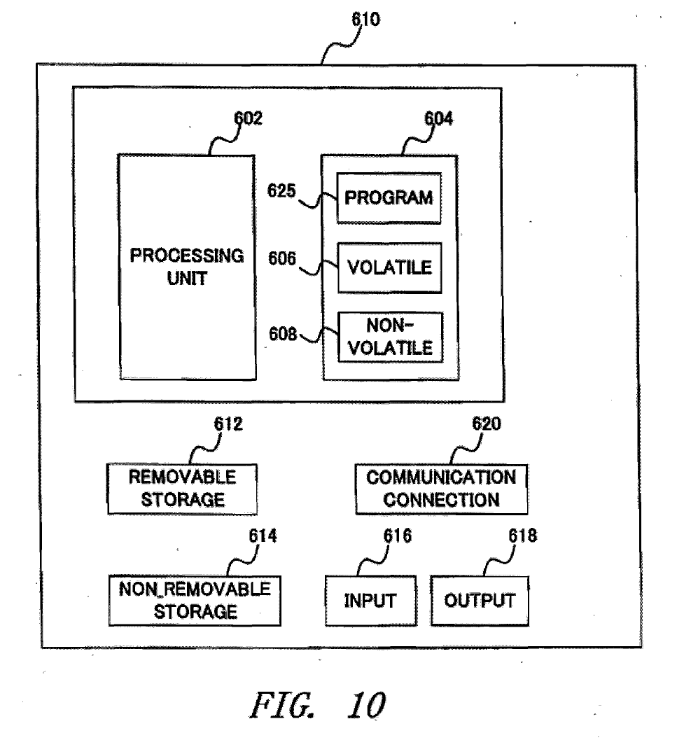

FIG. 9 shows a block diagram of hard disk drive 900 according to an embodiment of the invention. The hard disk drive 900 includes a magnetic disk 910 similar to the magnetic disk 11 shown in FIG. 1, but illustrated as a block diagram. The magnetic disk 910 includes user data 912 or space for user data. The magnetic disk 910 further includes hardware data 914 such as servo data, sync data, etc. In one embodiment, the hardware data 914 includes a defect table 916.

Using methods as described above, in one embodiment, the defect table 916 includes one or more defects larger that a first threshold size such as an ECC threshold. As discussed above, large defects are not correctable during drive operation using ECC therefore, their locations and sizes are mapped to the defect table 916. In one embodiment, small defects below the ECC threshold that are within the user data region 912 are not mapped because ECC can compensate for them.

In one embodiment, the defect table 916 includes one or more defects of a second size smaller than the ECC threshold size and larger than a second threshold size. In one embodiment, a second threshold size includes a detectability limit. In one embodiment, the second threshold size includes a more stringent size that is acceptable in a sector pulse region. As discussed above, smaller defects below the ECC threshold size are mapped when they fall into more sensitive regions that are searched with a higher defect detection standard. Because two defect detection standards are used, both defects above the ECC threshold and selected defects below the ECC threshold will be recorded in the defect table 916.

Although the defect table 916 is shown located on the magnetic disk 910, the invention is not so limited. Other locations such as RAM/ROM 920 located external to the magnetic disk 910 but within the drive 900 can also hold the defect map.

A block diagram of a computer system that executes selected methods as described is shown in FIG. 10. A general computing device in the form of a computer 610, may include a processing unit 602, memory 604, removable storage 612, and non-removable storage 614. Memory 604 may include volatile memory 606 and non-volatile memory 608. Computer 610 may include—or have access to a computing environment that includes—a variety of computer-readable media, such as volatile memory 606 and non-volatile memory 608, removable storage 612 and non-removable storage 614. Computer storage includes random access memory (RAM), read only memory (ROM), erasable programmable read-only memory (EPROM) & electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions. Computer 610 may include or have access to a computing environment that includes input 616, output 618, and a communication connection 620. The computer may operate in a networked environment using a communication connection to connect to one or more remote computers. The remote computer may include a personal computer (PC), server, router, network PC, a peer device or other common network node, or the like. The communication connection may include a Local Area Network (LAN), a Wide Area Network (WAN) or other networks. The controller 210 or other selected circuitry or components of the disk drive may be such a computer system.

Computer-readable instructions stored on a computer-readable medium are executable by the processing unit 602 of the computer 610. A hard drive, CD-ROM, and RAM are some examples of articles including a computer-readable medium. The computer program may also be termed firmware associated with the disk drive. In some embodiments, a copy of the computer program 625 can also be stored on the disk 11 of the disk drive.

The foregoing description of the specific embodiments reveals the general nature of the invention sufficiently that others can, by applying current knowledge, readily modify and/or adapt it for various applications without departing from the generic concept, and therefore such adaptations and modifications are intended to be comprehended within the meaning and range of equivalents of the disclosed embodiments.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

It is to be understood that the phraseology or terminology employed herein is for the purpose of description and not of limitation. Accordingly, the invention is intended to embrace all such alternatives, modifications, equivalents and variations as fall within the spirit and broad scope of the appended claims.

What is claimed is:

1. A method for checking a hard disk surface of a storage device for media defects comprising:
applying a first standard for defect detection in a first hard disk surface region; and
applying a second standard having a lower defect detection threshold than the first standard in a second hard disk surface region.

2. The method of claim 1, wherein the second hard disk surface region includes a region adjacent to a synchronization mark on the hard disk surface.

3. The method of claim 1, wherein applying the second standard includes checking for a defect size that is acceptable for a data region but unacceptably large for a synchronization mark region.

4. The method of claim 1, further including asserting a read/write gate at a time directly related to a servo gate pulse.

5. The method of claim 4, wherein asserting the read/write gate at the time directly related to the servo gate pulse includes asserting a read/write gate at a falling edge of the servo gate pulse.

6. The method of claim 4, wherein asserting the read/write gate at the time directly related to the servo gate pulse includes asserting the read/write gate at a chosen time after a falling edge of a servo gate pulse.

7. A method for checking a hard disk surface of a storage device for media defects comprising:
triggering assertion of a write gate using a falling edge of a servo gate pulse;
writing a set of test data in a sector;
triggering assertion of a read gate using a falling edge of a servo gate pulse to read the set of test data in the sector; and
comparing the written set of test data with the read set of test data to determine media defect locations.

8. The method of claim 7, wherein triggering assertion of the write gate using a falling edge of the servo gate pulse includes triggering assertion of a write gate after a time interval in close proximity to the falling edge of the servo gate pulse.

9. The method of claim 7, wherein comparing the written set of test data with the read set of test data includes:
applying a first standard for defect detection in a first hard disk surface region; and
applying a second standard having a lower defect detection threshold than the first standard in a second hard disk surface region.

10. The method of claim 9, wherein the first hard disk surface region includes a data region and the second hard disk surface region includes a synchronization mark region.

11. The method of claim 10, wherein the sector pulse region includes a window around a synchronization mark.

12. The method of claim 11, wherein applying the second standard having the lower defect detection threshold in the sector pulse region includes applying a second standard having a lower defect detection threshold in a window having a selectable size that is around the synchronization mark

13. The method of claim 9, wherein applying the first standard for defect detection in the data region includes not mapping defects that are below an Error Correction Code (ECC) threshold size.

14. The method of claim 13, wherein applying the second standard having a lower defect detection threshold in the synchronization region includes detecting and mapping defects that are below the ECC threshold size only when the defects are present in the synchronization region.

15. A disk drive apparatus comprising:
a disk, including a plurality of sectors, each sector having a plurality of tracks;
a storage media, located within the disk drive apparatus, configured to store a defect table of defect locations including locations that correspond to:
one or more defects larger that a first threshold size in a first region;
one or more defects of a second size smaller than the first threshold size and larger than a second threshold size in a second region.

16. The disk drive apparatus of claim 15, wherein the first region includes a data region and the second region includes a region adjacent to a sector pulse.

17. The disk drive apparatus of claim 16, wherein the defect of the second size is located within a spacing surrounding a synchronization mark, wherein the spacing is greater than or equal to a drive motor jitter tolerance.

18. The disk drive apparatus of claim 15, wherein the storage media is the disk.
